(19) United States
(12) Patent Application Publication
(10) Pub. No.: US 2020/0388628 A1
(43) Pub. Date: Dec. 10, 2020

(54) DISCONTINUOUS CHARGE TRAP LAYER MEMORY DEVICE

(71) Applicant: QUALCOMM Incorporated, San Diego, CA (US)

(72) Inventors: Xia LI, San Diego, CA (US); Bin YANG, San Diego, CA (US); Gengming TAO, San Diego, CA (US)

(21) Appl. No.: 16/435,823

(22) Filed: Jun. 10, 2019

(51) Int. Cl. H01L 27/11582; H01L 27/1157; H01L 21/28; H01L 21/762

(52) U.S. Cl. CPC H01L 27/11582; H01L 21/76224; H01L 21/28282; H01L 27/1157

(57) ABSTRACT

Certain aspects of the present disclosure are directed to a memory device and techniques for fabricating a memory device. One example memory device generally includes a substrate layer, a channel layer disposed above and having a longitudinal axis perpendicular to a horizontal plane of the substrate layer, and a plurality of charge trap (CT) regions disposed adjacent to the channel layer, the plurality of CT regions being separate regions that are electrically isolated from one another. In certain aspects, the memory device also includes a plurality of gate layers, each gate layer of the plurality of gate layers being disposed adjacent to one of the plurality of CT regions.

### FIELD OF THE DISCLOSURE

The teachings of the present disclosure relate generally to electronic systems, and more particularly, to a memory device.

### DESCRIPTION OF RELATED ART

Electronic devices including processors and memory are used extensively today in almost every electronic application. The processor controls the execution of program instructions, arithmetic functions, and access to memory and peripherals. In the simplest form, the processor executes program instructions by performing one or more arithmetic functions on data stored in memory.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

Certain aspects of the present disclosure are directed to a memory device. The memory device generally includes a substrate layer, a channel layer disposed above and having a longitudinal axis perpendicular to a horizontal plane of the substrate layer, and a plurality of charge trap (CT) regions disposed adjacent to the channel layer, the plurality of CT regions being separate regions that are electrically isolated from one another. In certain aspects, the memory device also includes a plurality of gate layers, each gate layer of the plurality of gate layers being disposed adjacent to one of the plurality of CT regions.

Certain aspects of the present disclosure are directed to a method for fabricating a memory device. The method generally includes forming a plurality of non-insulative layers and forming a plurality of dielectric layers, wherein the plurality of non-insulative layers and the plurality of dielectric layers are tiered. The method may also include forming a trench through the plurality of non-insulative layers and the plurality of dielectric layers such that edges of the plurality of non-insulative layers and the plurality of dielectric layers are aligned at a side of the trench. The method may also include recessing the edges of the plurality of non-insulative layers, forming a CT region adjacent to the recessed edge of each of the plurality of non-insulative layers, and forming a channel layer adjacent to the CT regions.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is an illustration of an exemplary system-on-chip (SoC) integrated circuit design, in accordance with certain aspects of the present disclosure.

FIG. 2 illustrates a cross-section of a portion of a memory stack of multiple memory cells in a memory device with discrete charge trap (CT) regions, in accordance with certain aspects of the present disclosure.

FIG. 3 illustrates a cross-section of a memory device showing multiple memory stacks, each having memory cells with discrete CT regions, in accordance with certain aspects of the present disclosure.

FIGS. 4A-4E illustrate example operations for fabricating a memory device, in accordance with certain aspects of the present disclosure.

FIG. 5 is a flow diagram illustrating example operations for fabricating a memory device, in accordance with certain aspects of the present disclosure.

### DETAILED DESCRIPTION

Certain aspects of the present disclosure are generally directed to a three-dimensional (3D) NAND flash memory implemented with a discontinuous charge trap (CT) layer where each memory cell in the flash memory has a separate, discrete CT region, preventing (or at least reducing) movement of charge between memory cells. The discrete CT regions prevent cell disturbance for small pitch implementations and enable cell pitch scaling.

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

The various aspects will be described in detail with reference to the accompanying drawings. Wherever possible, the same reference numbers will be used throughout the drawings to refer to the same or like parts. References made to particular examples and implementations are for illustrative purposes, and are not intended to limit the scope of the disclosure or the claims.

The terms “computing device” and “mobile device” are used interchangeably herein to refer to any one or all of servers, personal computers, smartphones, cellular telephones, tablet computers, laptop computers, netbooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., ROM, RAM, flash, etc.), and resources (e.g., timers, voltage regulators, oscillators, etc.), any or all of which may be included in one or more cores.

A number of different types of memories and memory technologies are available or contemplated in the future, all of which are suitable for use with the various aspects of the present disclosure. Such memory technologies/types include dynamic random-access memory (DRAM), static random-access memory (SRAM), non-volatile random-access memory (NVRAM), flash memory (e.g., embedded multimedia card (eMMC) flash), pseudostatic random-access memory (PSRAM), double data rate synchronous dynamic random-access memory (DDR SDRAM), and other random-access memory (RAM) and read-only memory (ROM) technologies known in the art. A DDR SDRAM memory may be a DDR type 1 SDRAM memory, DDR type 2 SDRAM memory, DDR type 3 SDRAM memory, or a DDR type 4 SDRAM memory. Each of the above-mentioned memory technologies includes, for example, elements suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

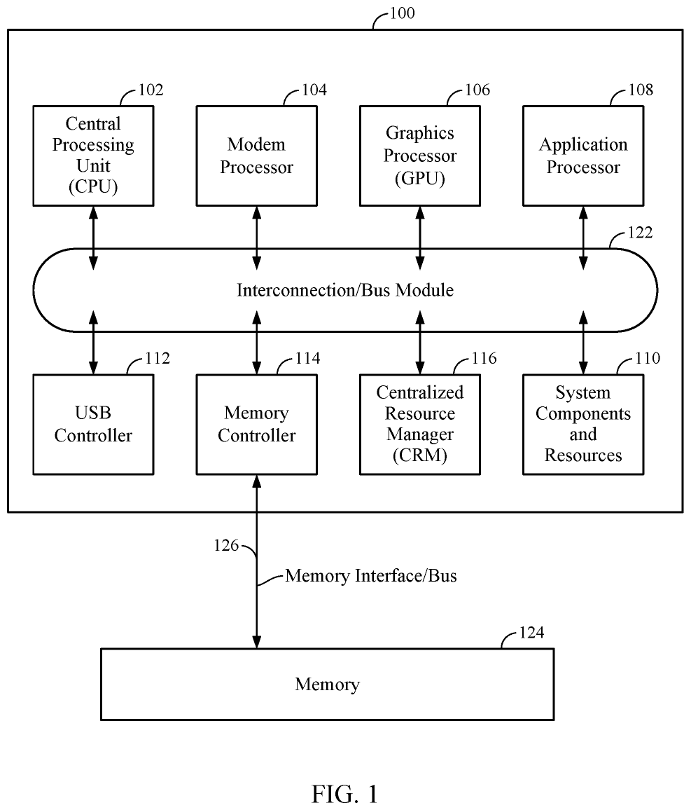

FIG. 1 illustrates example components and interconnections in a system-on-chip (SoC) 100 suitable for implementing various aspects of the present disclosure. The SoC 100 may include a number of heterogeneous processors, such as a central processing unit (CPU) 102, a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., voltage rails), as well as for more coordinated cooperation between cores.

The SoC 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The SoC 100 may further include a Universal Serial Bus (USB) controller 112, one or more memory controllers 114, and a centralized resource manager (CRM) 116. The SoC 100 may also include an input/output module (not illustrated) for communicating with resources external to the SoC, each of which may be shared by two or more of the internal SoC components.

The processors 102, 104, 106, 108 may be interconnected to the USB controller 112, the memory controller 114, system components and resources 110, CRM 116, and/or other system components via an interconnection/bus module 122, which may include an array of reconfigurable logic gates and/or implement a bus architecture (e.g., CoreConnect, AMBA, etc.). Communications may also be provided by advanced interconnects, such as high performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously.

The memory controller 114 may be a specialized hardware module configured to manage the flow of data to and from a memory 124 via a memory interface/bus 126. In certain aspects, the memory may be a flash memory device implemented with a discrete charge trap layer, as described in more detail herein.

The memory controller 114 may comprise one or more processors configured to perform read and write operations with the memory 124. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the memory 124 may be part of the SoC 100.

### EXAMPLE MEMORY DEVICE WITH DISCRETE CHARGE TRAP REGIONS

Three-dimensional (3D) NAND flash memory technology has allowed for higher bit density with good performance and reliability by stacking memory cells vertically. Memory cells may be stacked vertically via a cylindrical poly-silicon channel disposed above a substrate to form the 3D NAND flash memory. NAND flash memory uses charge trap transistors to store data. That is, the NAND flash memory includes a set of transistors connected in series, each transistor having a charge trap gate, as described in more detail herein. For example, a bit-line of the NAND flash memory may be pulled to a logic low state only when all the series-connected charge trap transistors are at an on state and a selected charge trap transistor has a gate that is at a low read state. A NAND flash memory may include multiple transistor stacks, each stack having a poly-silicon (poly-Si) channel used to implement a set of series-connected transistors.

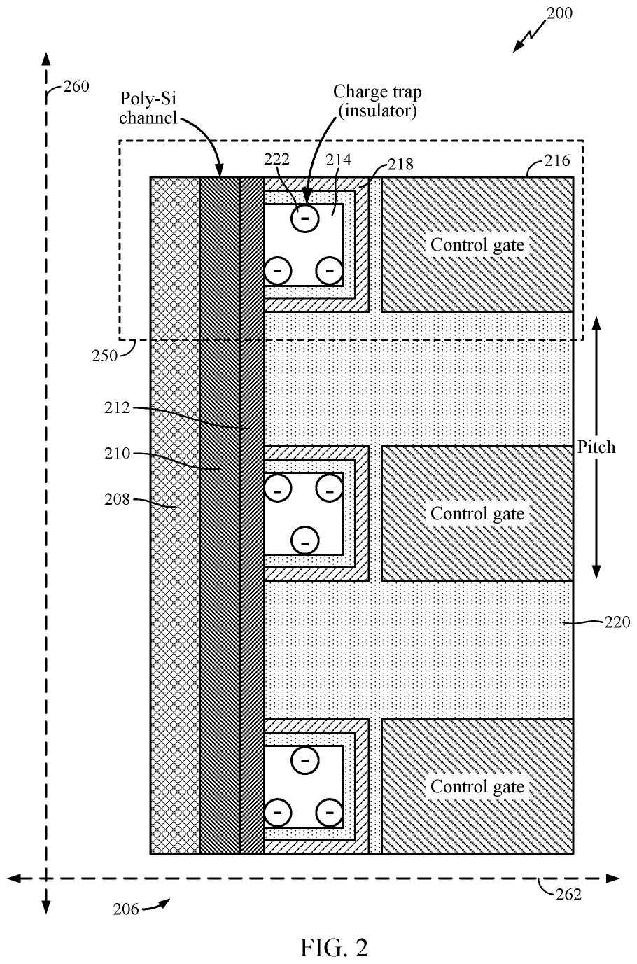

Charge may be trapped in a cylindrical charge trap (CT) dielectric layer adjacent to the channel (e.g., surrounding the channel). Conventionally, the CT dielectric layer may be a continuous region used to implement multiple memory cells. The CT dielectric layer may be surrounded by a metal gate region in each memory cell to program the respective memory cell by controlling the storage of charge in the CT dielectric region of the cell. However, charge may be lost by migrating through the continuous CT dielectric layer, especially when the memory cells are implemented with a small cell pitch. The pitch of a memory device generally refers to the distance between the gates of adjacent memory cells, as illustrated in FIG. 2.

A continuous CT dielectric region allows for charge to move along the CT dielectric layer between memory cells (e.g., from one cell's CT dielectric region to an adjacent cell's CT dielectric region). The movement of charge between memory cells causes cell disturbances when the memory cells are implemented with a small pitch, and as a result, prevents vertical scaling of cell pitch to increase bit density. To increase the bit density of the 3D NAND flash memory, multiple NAND layers may instead be stacked on top of one another. However, stacking NAND layers on top of one another significantly increases cost and process complexity.

Certain aspects of the present disclosure are generally directed to a 3D NAND flash memory implemented with a discontinuous CT layer in a memory stack, preventing (or at least reducing) movement of charge between cells. The discrete CT layer prevents (or at least reduces) memory cell disturbances for small pitch implementations and enables cell pitch scaling.

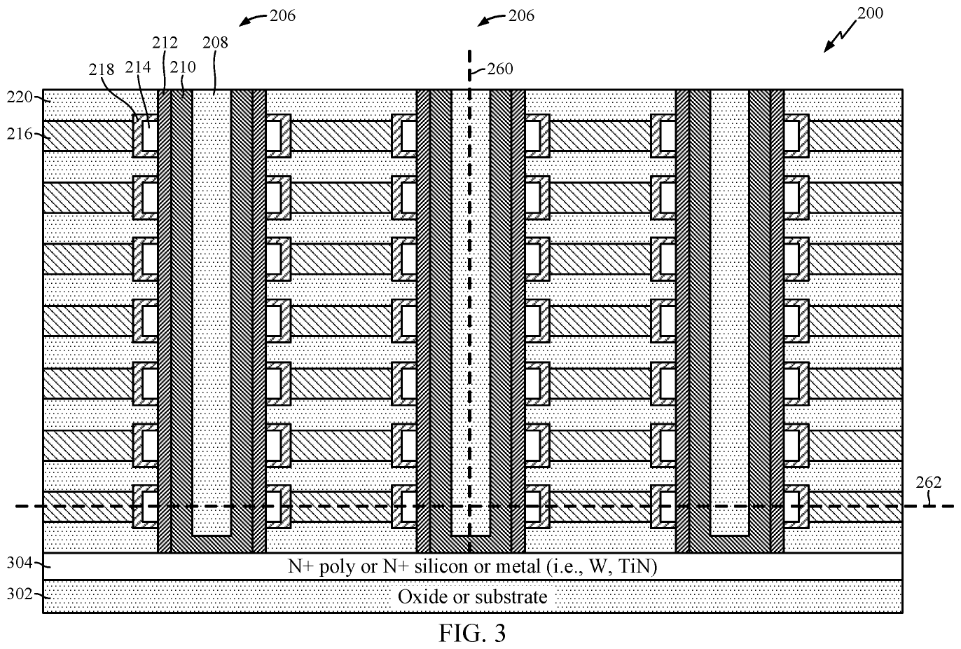

FIG. 2 illustrates a cross-section of a portion of a memory stack 206 of a memory device 200 having multiple memory cells (e.g., memory cell 250), in accordance with certain aspects of the present disclosure. As illustrated, a stack of memory cells may be implemented vertically with discrete CT regions. For example, the memory stack 206 includes a dielectric layer 208 (e.g., an oxide region, which may have a cylindrical shape). The dielectric layer 208 may be a vertical layer having a longitudinal axis 260 that is perpendicular to a horizontal axis 262 of horizontal layers used to form gate regions of the memory device 200, as described in more detail herein with respect to FIG. 3.

A non-insulative layer 210 (e.g., a channel layer, which may be a poly-silicon channel layer) may be disposed adjacent to the dielectric layer 208. For example, the non-insulative layer 210 may surround the dielectric layer 208 (e.g., cylindrical oxide region). As used herein, a non-insulative layer or region generally refers to a layer or region of conductive or semiconductive material.

A dielectric layer 212 (e.g., a block oxide layer or tunnel layer) may be disposed adjacent to and surround the non-insulative layer 210 to electrically isolate the non-insulative layer 210 from discrete CT regions 214 of the memory device 200. For example, a CT region 214 (e.g., a dielectric region) may be disposed adjacent to and surround a section of the dielectric layer 212. Charge 222 may be stored in the CT region 214 to program a respective memory cell via a control gate region 216 that is isolated from the CT region 214 via a dielectric region 218 (e.g., a block oxide region). As illustrated, the control gate regions 216 of the memory cells are isolated from one another via a dielectric layer 220 (e.g., oxide layer).

FIG. 3 illustrates a cross-section of the memory device 200, in accordance with certain aspects of the present disclosure. As illustrated, the memory device 200 may include a substrate layer 302 (e.g., oxide layer), over which a non-insulative layer 304 may be disposed. For example, the non-insulative layer 304 may be implemented with poly-silicon (e.g., N+ poly-silicon), silicon (e.g., N+ silicon), or metal such as tungsten (W) or titanium nitride (TiN).

Above the non-insulative layer 304, multiple vertical memory stacks (e.g., memory stack 206) of memory cells may be implemented. For example, as described herein with respect to FIG. 2, the memory stack 206 may include a dielectric layer 208 (e.g., cylindrical oxide region), a non-insulative layer 210 (e.g., a channel layer), a dielectric layer 212 (e.g., a tunnel layer), a CT region 214 per memory cell, a control gate region 216 per memory cell, and a dielectric region 218 (e.g., block oxide region) per memory cell. As illustrated, the dielectric layer 212, the non-insulative layer 210 (e.g., channel layer), and the dielectric layer 208 are vertical layers (e.g., cylindrical layers having a vertically oriented longitudinal axis 260) that are perpendicular to the horizontal plane of the substrate layer 302 having a horizontal axis 262, thereby forming a 3D memory device.

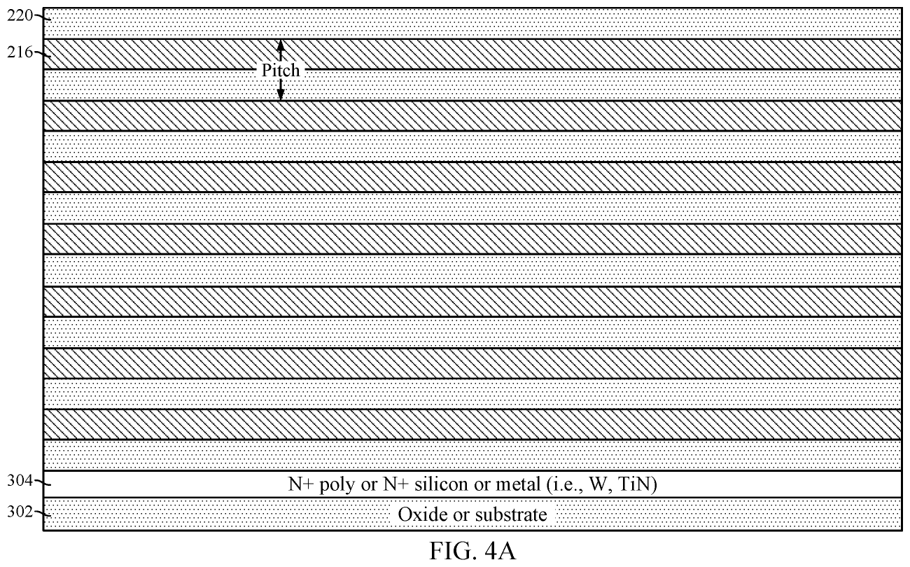

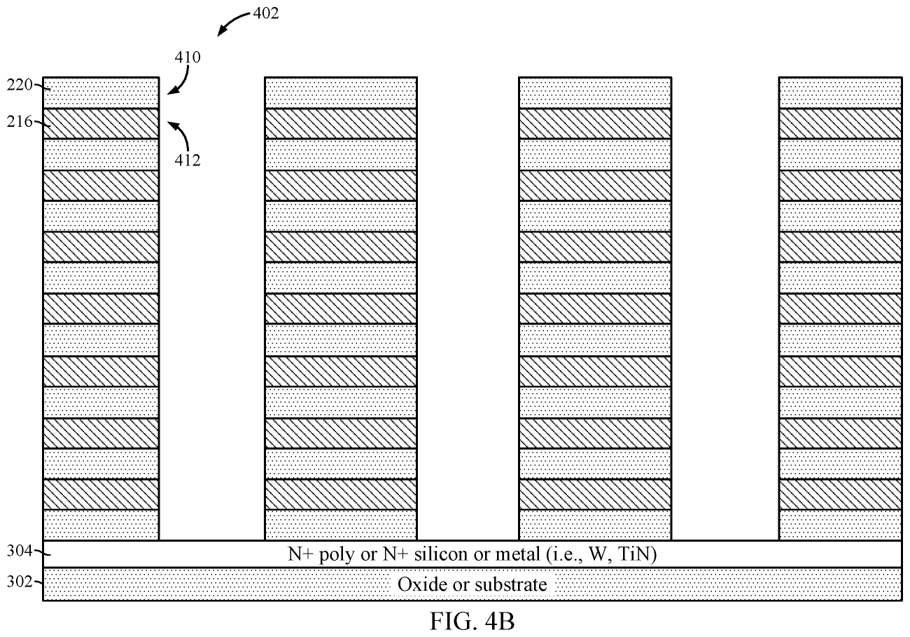

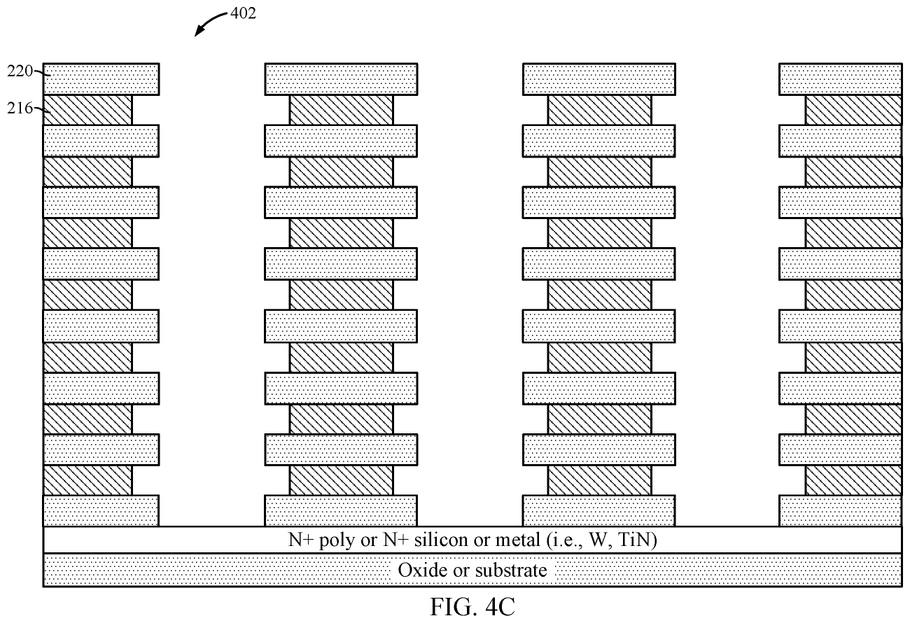

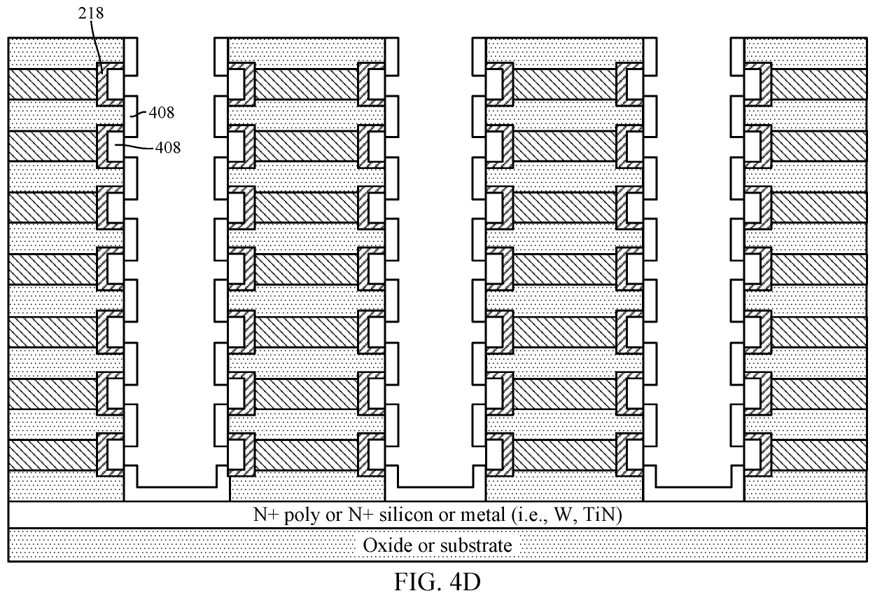

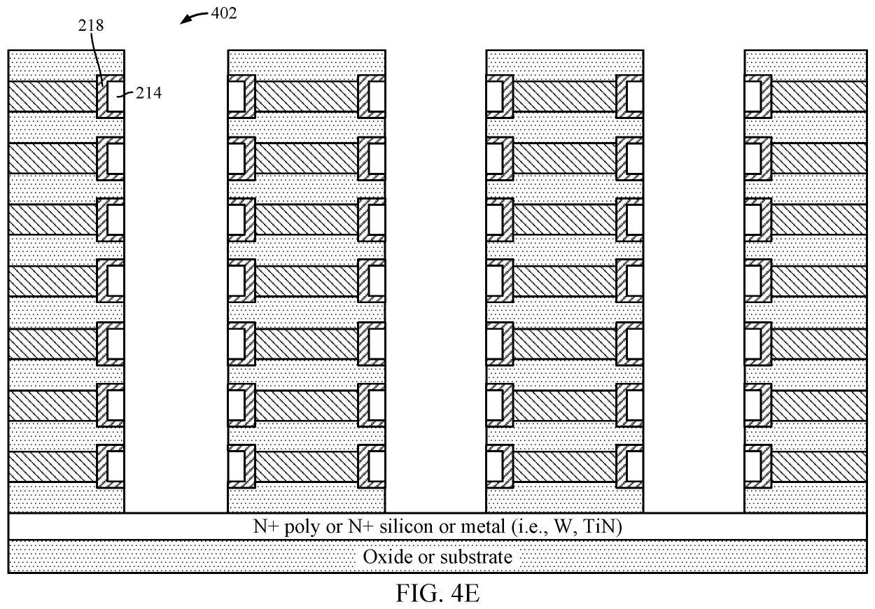

FIGS. 4A-4E illustrate example operations for fabricating the memory device 200, in accordance with certain aspects of the present disclosure. As illustrated in FIG. 4A, multiple dielectric layers (e.g., dielectric layer 220) and non-insulative layers (e.g., non-insulative layer 304 and control gate region 216) may be tiered above the substrate layer 302. The thickness of the dielectric layers and non-insulative layers may be controlled to set the pitch of the memory device.

As illustrated in FIG. 4B, a hardmask (e.g., silicon nitride (Si₃N₄) or silicon oxynitride (SiOₓN_{y})) may be deposited, followed by a photo and etch process to form trenches (e.g., trench 402) through the tiered dielectric and non-insulative layers. The edges 410, 412 of the dielectric layer (e.g., layer 220) and the control gate layer (e.g., region 216), respectively, may be aligned at a side of the trench 402 at this stage. As illustrated in FIG. 4C, the control gate layers may be selectively recessed via a wet etch process (e.g., via hydrogen peroxide (H₂O₂) heated to 50° Celsius). In other words, the edges of the control gate layers (e.g., control gate region 216) are recessed without recessing the edges of the dielectric layers (e.g., dielectric layer 220).

As illustrated in FIG. 4D, dielectric material may be deposited in the trenches (e.g., trench 402) to form the block oxide regions (e.g., dielectric region 218). CT material 408 (e.g., silicon nitride (Si₃N₄)) may be deposited after formation of the block oxide regions. As illustrated in FIG. 4E, the CT material 408 may be etched back to form the CT regions (e.g., CT region 214) of the memory device 200 such that an edge of the CT material 408 (or CT region 214) is aligned with the edges of the dielectric layers (e.g., dielectric layer 220) at the side of the trench. As illustrated in FIG. 3, poly film may then be deposited to form the non-insulative layer 210 (e.g., a poly-silicon channel region) and/or the dielectric layer 208 (e.g., oxide layer). Chemical-mechanical polishing (CMP) of the memory device 200 may then be performed to planarize the top surface of the memory device 200, followed up with contact and metallization to connect the memory cells of the memory device 200.

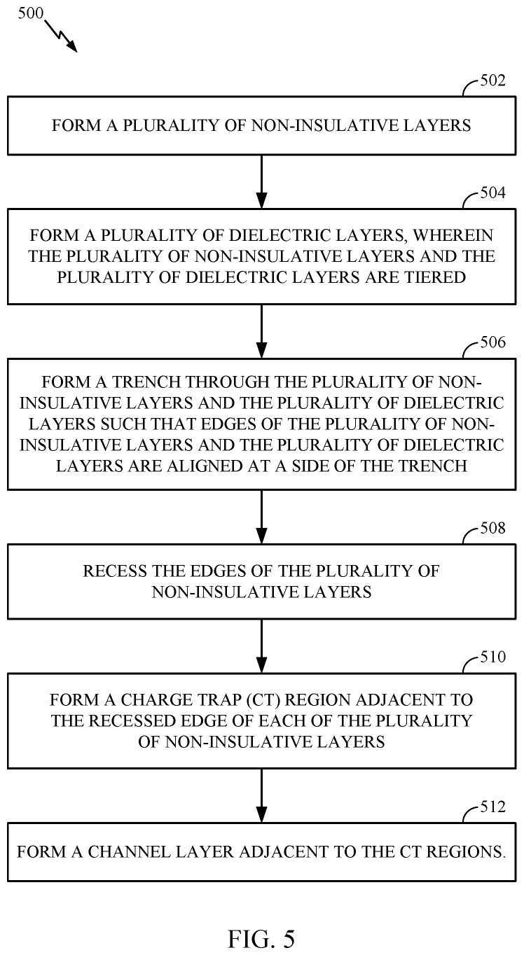

FIG. 5 is a flow diagram illustrating example operations 500 for fabricating a memory device (e.g., memory device 200), in accordance with certain aspects of the present disclosure. The operations 500 may be performed by a semiconductor fabrication facility.

The operations 500 begin, at block 502, with the facility forming a plurality of non-insulative regions (e.g., control gate region 216), and at block 504, forming a plurality of dielectric regions (e.g., dielectric layer 220), wherein the plurality of non-insulative regions and the plurality of dielectric regions are tiered. At block 506, the facility forms a trench (e.g., trench 402) through the plurality of non-insulative regions and the plurality of dielectric regions such that edges of the plurality of non-insulative regions and the plurality of dielectric regions are aligned at a side of the trench, and at block 508, the facility recesses the edges of the plurality of non-insulative regions. At block 510, the facility forms a CT region (e.g., CT region 214) adjacent to the recessed edge of each of the plurality of non-insulative regions, and at block 512, forms a channel layer (e.g., non-insulative layer 210) adjacent to the CT regions.

In certain aspects, the operations 500 may also include forming a plurality of dielectric regions (e.g., dielectric region 218) prior to forming the charge trap regions, each of the plurality of dielectric regions being between one of the charge trap regions and a respective one of the plurality of non-insulative regions. In certain aspects, forming the charge trap regions includes: (a) depositing charge trap material in the trench after the recessing of the edges of the plurality of non-insulative regions and (b) etching the charge trap material such that an edge of the charge trap material is aligned with the edges of the plurality of dielectric regions at the side of the trench.

In certain aspects, the operations 500 may also include forming another non-insulative region (e.g., non-insulative layer 304) above a substrate (e.g., substrate layer 302). The plurality of non-insulative regions and the plurality of dielectric regions may be formed above the other non-insulative region.

In certain aspects, the operations 500 also include filling the trench with dielectric material after forming the channel layer to form a dielectric region (e.g., dielectric layer 208). The channel layer may laterally surround the dielectric region. In certain aspects, a portion of the channel layer may be further disposed adjacent to a bottom surface of the dielectric region. In certain aspects, the dielectric region may have a cylindrical shape. In certain aspects, the CT regions are separate regions that are electrically isolated from one another. In certain aspects, the operations 500 also include forming a dielectric layer (e.g., dielectric layer 212) between the channel layer and the CT regions.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein. The algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

1. A memory device, comprising:
a substrate layer;
a channel layer disposed above and having a longitudinal axis perpendicular to a horizontal plane of the substrate layer;
a plurality of charge trap (CT) regions disposed adjacent to the channel layer, the plurality of CT regions being separate regions that are electrically isolated from one another; and
a plurality of gate layers, each gate layer of the plurality of gate layers being disposed adjacent to one of the plurality of CT regions.

2. The memory device of claim 1, further comprising a dielectric layer disposed above and having a longitudinal axis perpendicular to the horizontal plane of the substrate layer, wherein the channel layer laterally surrounds the dielectric layer.

3. The memory device of claim 2, wherein a portion of the channel layer is further disposed adjacent to a bottom surface of the dielectric layer.

4. The memory device of claim 2, wherein each of the plurality of CT regions laterally surrounds the channel layer.

5. The memory device of claim 2, wherein the dielectric layer has a cylindrical shape.

6. The memory device of claim 2, further comprising a non-insulative layer disposed between the substrate layer and a bottom surface of the channel layer.

7. The memory device of claim 1, further comprising:
a dielectric layer disposed between the channel layer and the plurality of CT regions.

8. The memory device of claim 1, further comprising:
a dielectric region disposed between the gate layer and the CT region.

9. The memory device of claim 1, further comprising a plurality of memory cells, each of the plurality of memory cells comprising one of the plurality of CT regions, one of the plurality of gate layers, and a portion of the channel layer.

10. The memory device of claim 1, further comprising a dielectric layer disposed between each pair of adjacent gate layers.

11. The memory device of claim 1, wherein the memory device is configured as a NAND flash memory.

12-20. (canceled)

21. A method for fabricating a memory device, comprising:
forming a channel layer above and having a longitudinal axis perpendicular to a horizontal plane of a substrate layer;
forming a plurality of charge trap (CT) regions adjacent to the channel layer, the plurality of CT regions being separate regions that are electrically isolated from one another; and
forming a plurality of gate layers, each gate layer of the plurality of gate layers being formed adjacent to one of the plurality of CT regions.

22. The method of claim 21, further comprising forming a dielectric layer above and having a longitudinal axis perpendicular to the horizontal plane of the substrate layer, wherein the channel layer laterally surrounds the dielectric layer.

23. The method of claim 22, wherein a portion of the channel layer is further formed adjacent to a bottom surface of the dielectric layer.

24. The method of claim 22, wherein each of the plurality of CT regions laterally surrounds the channel layer.

25. The method of claim 22, wherein the dielectric layer has a cylindrical shape.

26. The method of claim 22, further comprising forming a non-insulative layer such that the non-insulative layer is between the substrate layer and a bottom surface of the channel layer.

27. The method of claim 21, further comprising forming a dielectric layer such that the dielectric layer is between the channel layer and the plurality of CT regions.

28. The method of claim 21, further comprising forming a dielectric region such that the dielectric region is between the gate layer and the CT region.

29. The method of claim 21, further comprising forming a plurality of memory cells, each of the plurality of memory cells comprising one of the plurality of CT regions, one of the plurality of gate layers, and a portion of the channel layer.
